(19) United States
(12) Patent Application Publication
(10) Pub. No.: US 2007/0200252 A1
(43) Pub. Date: Aug. 30, 2007

(54) Circuit board apparatus, circuit component reinforcing method and electronic device

(76) Inventor: Kenji Kaji, Akishima-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/710,841

(22) Filed: Feb. 26, 2007

(30) Foreign Application Priority Data
Feb. 28, 2006 (JP) 2006-051528

(51) Int. Cl. H01L 23/48

(52) U.S. Cl. 257/778

(57) ABSTRACT

According to one embodiment, a circuit board apparatus includes a substrate mounting a semiconductor component. A circuit board mounts the substrate. A solder bonding portion is provided in a side surface of the substrate. A pad is provided on the circuit board and solder bonded to the solder bonding portion.

### CROSS-REFERENCE TO RELATED APPLICATIONS

This application is based upon and claims the benefit of priority from Japanese Patent Application No. 2006-051528, filed Feb. 28, 2006, the entire contents of which are incorporated herein by reference.

### BACKGROUND

1. Field

One embodiment of the invention relates to a circuit board apparatus, a circuit component reinforcing method, and an electronic device which can be applied to a portable information processing apparatus.

2. Description of the Related Art

In a portable information processing apparatus housing a semiconductor device such as a CPU, an MPU, etc., a mechanism is used for maintaining a stable operation against shock, vibration, etc. at the time of carrying/using the information processing apparatus. As for such reinforcing techniques, there is a technique which provides a reinforcing bump between a face down bonded component and a printed-wiring board mounting the face down bonded component (for example, see Japanese Patent Application KOKAI Publication No. 2000-200854). The reinforcing bump is for reinforcing bonding strength. There is another reinforcing technique which provides an adhesive between the face down bonded component and the printed-wiring board, so as to prevent detachment.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary sectional view of a circuit board apparatus according to a first embodiment of the invention;

FIG. 2 is an exemplary partial plan view of a substrate of the circuit board apparatus according to the first embodiment;

FIG. 3 is an exemplary partial sectional view of the circuit board apparatus according to the first embodiment;

FIG. 4 is an exemplary plan view of the circuit board apparatus according to the first embodiment;

FIG. 5 is an exemplary sectional view of a circuit board apparatus according to a second embodiment of the invention; and

FIG. 6 is an exemplary perspective view of an electronic device using the circuit board apparatus according to the first embodiment of the invention.

### DETAILED DESCRIPTION

Various embodiments according to the invention will be described hereinafter with reference to the accompanying drawings. In general, according to one embodiment of the invention, a circuit board apparatus includes: a substrate mounting a semiconductor component; a circuit board mounting the substrate; a solder bonding portion provided in a side surface of the substrate; and a pad provided on the circuit board and solder bonded to the solder bonding portion.

Embodiments of the invention relate to a reinforcing technique which can be applied to a circuit board apparatus mounting a face down bonded component, such as a BGA (ball grid array), a CSP (chip size package), an LGA (land grid array), etc. A circuit board apparatus according to the embodiments of the invention mounts a semiconductor component, and realizes a specific function circuit for operating the semiconductor component. For example, the circuit board apparatus can realize a main circuit in various portable electronic devices, such as a portable computer, a PDA, an audio player, a video player, etc.

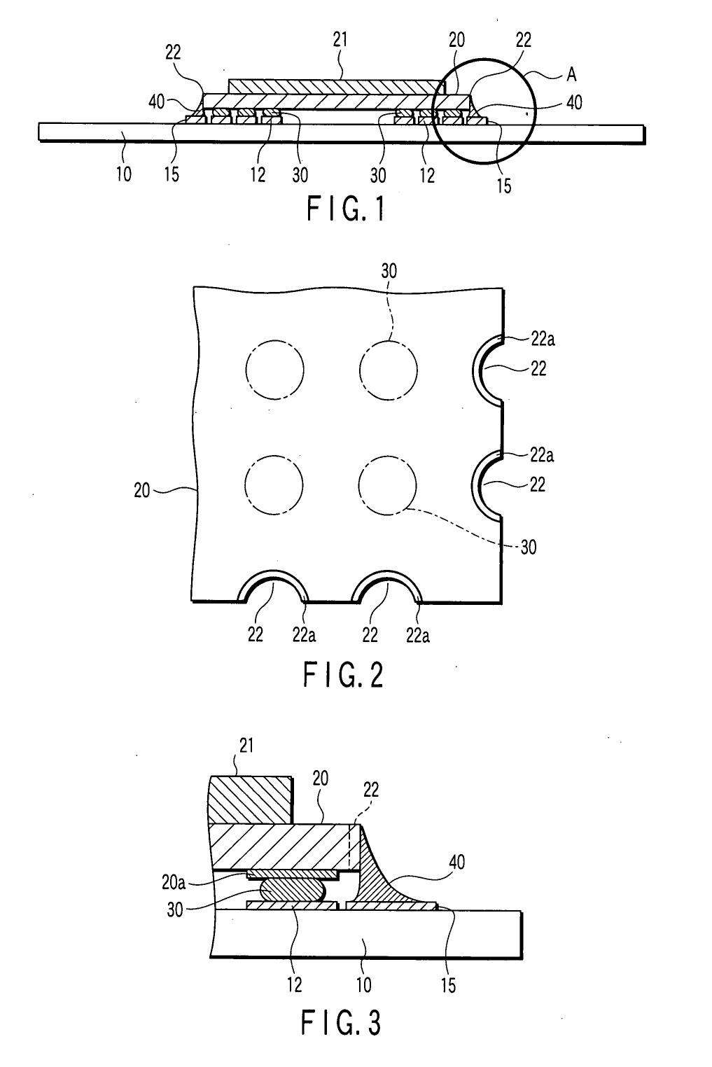

FIGS. 1 through 4 show exemplary structures of a circuit board apparatus according to a first embodiment of the invention.

As shown in FIG. 1, the circuit board apparatus according to the first embodiment of the invention includes a circuit board 10 and a substrate 20. In each embodiment including the first embodiment, it is assumed that the circuit board 10 is a motherboard. The first embodiment shows a case where the substrate serves as a BGA component.

The motherboard 10 mounts the substrate 20 thereon. The substrate 20 is mounted on the motherboard 10 by interposing solder balls 30 between pads of the substrate 20 and pads 12 of the motherboard 10. It should be noted that FIG. 1 shows only the pads (connecting terminal electrodes) 12 of the motherboard 10. The substrate 20 is a small substrate having a rectangular board shape. Mounting means for mounting the semiconductor component 21 is provided on a top surface of the substrate 20.

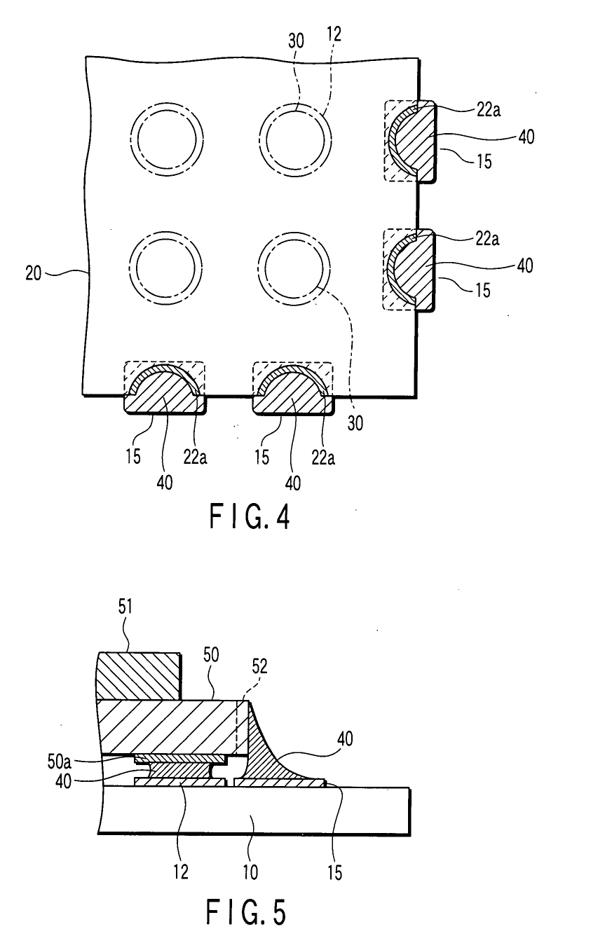

FIG. 2 is a plan view showing an exemplary partial structure of the substrate 20 in a portion indicated by a circle A in FIG. 1. FIG. 3 is an enlarged sectional view of the portion indicated by the circle A in FIG. 1. FIG. 4 is a plan view of the portion indicated by the circle A in FIG. 1.

As shown in FIG. 2, the substrate 20 is provided with a plurality of solder bonding surfaces (portions) 22 in side surfaces of each of four corner portions. In this embodiment, the solder bonding portions 22 are realized by semi-circle plated through-holes. In a manufacturing process of substrates manufactured by cutting out a plurality of substrates from a single base material, the semi-circle plated through-holes can be easily formed by forming plated through-holes on cut lines of the base material, and separating the substrates along the cut lines. Conductive patterns 22a, which are plating layers (e.g., copper plating layers) of the plated through-holes 22, serve as reinforcing solder bonding surfaces (portions). The conductive patterns 22a are maintained in a state where a good wettability is obtained with respect to solder reflowing. For example, by applying a conductive paste to the conductive patterns 22a immediately after the formation of the conductive patterns 22a, it is possible to maintain a state where a good wettability is obtained.

The motherboard 10 is provided with reinforcing pads 15 corresponding to the conductive patterns 22a serving as the above-mentioned solder bonding surfaces (portions). The reinforcing pads 15 are provided around a substrate mounting surface.

The reinforcing pads 15 may be patterns each formed in a so-called island-shape and provided on the substrate mounting surface. However, in a case where the motherboard 10 is formed by a printed-wiring board, and through-hole lands can be formed at the positions of the pads, the through-hole lands serve as the reinforcing pads 15 for reinforcing strength.

After the substrate 20 is mounted on the substrate mounting surface of the motherboard 10, the conductive patterns 22a provided in the side surfaces of the substrate 20 are bonded, by a solder 40, to the reinforcing pads 15. This solder bonded portions (the portions indicated by reference numeral 40 in FIGS. 1, 3 and 4) function as reinforcing structure portions of the substrate 20. That is, the solder bonded portions function as physical reinforcing structure portions for protecting circuits which connect the semiconductor component 21 to the motherboard 10.

The solder bonding of the reinforcing pads 15 to the conductive patterns 22a is performed at the time of a reflowing process for mounting the substrate 20 on the motherboard 10. However, the above-mentioned solder bonding can be performed after the reflowing process. In the reflowing process, by applying the conductive paste to the conductive patterns 22a as mentioned above, it is possible for the conductive paste to draw melted solder of solder balls, which are provided on the reinforcing pads 15, toward the conductive patterns 22a. Thus, it is possible to more positively form solder masses between the reinforcing pads 15 and the conductive patterns 22a.

In the above-mentioned first embodiment, the BGA-type substrate is used as the substrate 20. FIG. 5 shows a second embodiment of the invention which uses a CSP-type substrate or an LGA-type substrate as the substrate 20.

A circuit board apparatus according to the second embodiment shown in FIG. 5 includes the motherboard 10 and a CSP-type or LGA-type substrate 50. Mounting means for mounting a semiconductor component 51 is provided on a top surface of the substrate 50.

The substrate 50 is provided with a plurality of solder bonding surfaces (portions) 52 in side surfaces of four corner portions of the substrate 50 or in the side surfaces of the four corner portions and the side surface of each side of the substrate 50. The solder bonding portions 52 are formed by forming, for example, semi-circle plated through-holes similar to those in the above-mentioned first embodiment.

The solder bonding portions 52 are bonded, by the solder 40, to the reinforcing pads 15 provided around the substrate mounting surface of the motherboard 10. As a result, solder bonding portions (indicated by the reference numeral 40 in FIG. 5) function as reinforcing structure portions of the substrate 50. That is, the solder bonding portions function as physical reinforcing structure portions for protecting circuits which connect the semiconductor component 51 to the motherboard 10.

In the second embodiment, the solder bonding portions 52 provided in the substrate 50 are realized by the semi-circle plated through-holes similar to those in the first embodiment. However, the solder bonding portions 52 are not limited to the semi-circle plated through-holes. For example, in a manufacturing process of substrates manufactured by cutting out a plurality of substrates from a single base material, solder bonding portions can be formed by: forming through-holes on cut lines of the base material; embedding, in the through-holes, a metal mass which is suitable for soldering so that the metal mass adheres to wall surfaces of the through-holes; and thereafter separating the substrates along the cut lines.

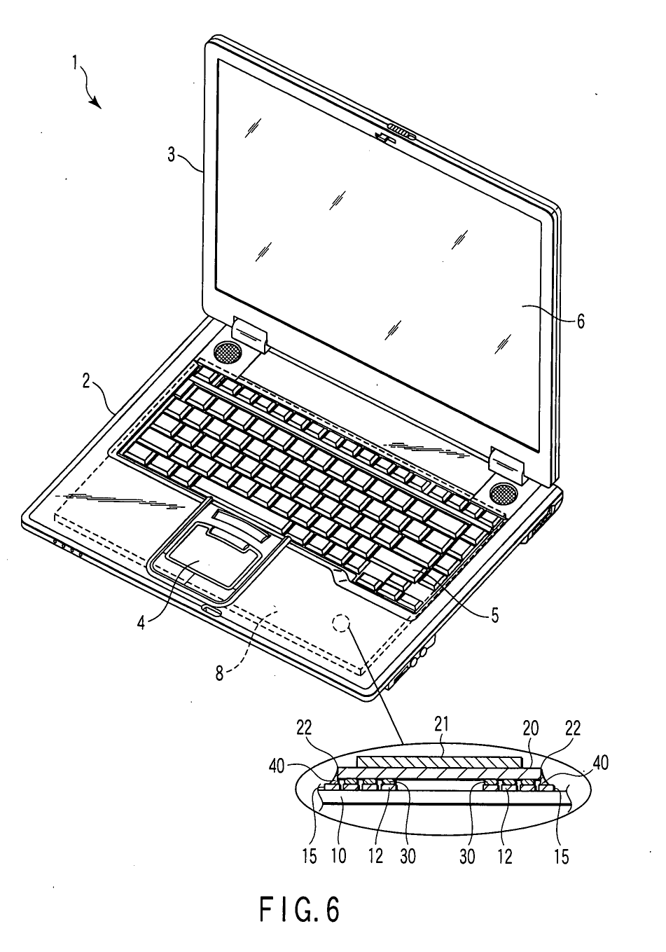

FIG. 6 shows an exemplary structure of an electronic device using the circuit board apparatus shown in the first embodiment. More specifically, FIG. 6 shows a case where the circuit board apparatus according to the above-mentioned first embodiment is applied to a small electronic apparatus such as a portable computer, etc.

In FIG. 6, a display housing 3 is rotatably attached to a main body 2 of a portable computer 1 via a hinge mechanism. The main body 2 is provided with operation units such as a pointing device 4, a keyboard 5, etc. The display housing 3 is provided with a display device 6 such as an LCD, etc.

Additionally, the main body 2 is provided with a circuit board apparatus 8 incorporating therein a control circuit for controlling the display device 6 and the operation units such as the pointing device 4, the keyboard 5, etc. The circuit board apparatus 8 is realized by using the circuit board apparatus according to the first embodiment shown in FIGS. 1 through 4.

In the circuit board apparatus 8, the conductive patterns 22a provided in the side surfaces of the substrate 20 are bonded to the reinforcing pads 15, which are provided around the substrate mounting surface of the motherboard 10. As a result, the solder bonding portions function as the reinforcing structure portions of the substrate 20, and thus protect circuits connecting the semiconductor component 21 to the motherboard 10. Hence, it is possible to significantly reduce improper operations, malfunctions, etc. due to poor contacting, disconnection of each circuit in the substrate 20 caused by external stress such as shock, vibration, etc. at the time of carrying/using the electronic device. Thus, it is possible to provide a reliable electronic device which operates stably. Further, the circuit board apparatus 8 can be realized by using the circuit board apparatus according to the second embodiment of the invention. Also in this case, it is possible to obtain the above-mentioned effects.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A circuit board apparatus, comprising:
a substrate mounting a semiconductor component;
a circuit board mounting the substrate;
a solder bonding portion provided in a side surface of the substrate; and
a pad provided on the circuit board and solder bonded to the solder bonding portion.

2. The circuit board apparatus according to claim 1, wherein the solder bonding portion comprises a semi-circle portion of a plated through-hole.

3. The circuit board apparatus according to claim 1, wherein the semiconductor component comprises a face down bonded component.

4. The circuit board apparatus according to claim 1, wherein the substrate comprises one or more solder bonding portions in a corner portion of the substrate.

5. The circuit board apparatus according to claim 1, wherein the pad comprises a through-hole land.

6. A circuit component reinforcing method for a circuit board apparatus including a substrate mounting a semiconductor component and a circuit board mounting the substrate, the circuit component reinforcing method comprising:
forming a solder bonding portion on a side surface of the substrate;
providing, on the circuit board, a pad at a position corresponding to the solder bonding portion; and
solder bonding the solder bonding portion to the pad to reinforce the substrate.

7. The circuit component reinforcing method according to claim 6, wherein forming the solder bonding portion comprises forming the solder bonding portion by forming a semi-circle portion of a plated through-hole.

8. The circuit component reinforcing method according to claim 7, wherein the plated through-hole is formed by forming a through-hole on a cut line of a base material along which a plurality of substrates are cut out.

9. The circuit component reinforcing method according to claim 6, wherein the semiconductor component comprises a face down bonded component.

10. The circuit component reinforcing method according to claim 6, wherein forming the solder bonding portion comprises forming one or more solder bonding portions in a corner portion of the substrate.

11. The circuit component reinforcing method according to claim 6, wherein the pad comprises a through-hole land.

12. An electronic device, comprising:
a substrate mounting a semiconductor component;
a circuit board mounting the substrate and connected to the semiconductor component; and
a reinforcing structure in which a solder bonding portion provided on a side surface of the substrate is solder bonded to a pad provided on the circuit board to reinforce the substrate.

13. The electronic device according to claim 12, wherein the solder bonding portion comprises a semi-circle portion of a plated through-hole.

14. The electronic device according to claim 13, wherein the semiconductor component comprises a face down bonded component.

15. The electronic device according to claim 14, wherein the substrate comprises one or more solder bonding portions in a corner portion of the substrate.
